(19) United States
(12) Patent Application Publication
(10) Pub. No.: US 2011/0058408 A1
(43) Pub. Date: Mar. 10, 2011

(54) MEMORY CELL ARRANGEMENTS; MEMORY CELL READER; METHOD FOR DETERMINING A MEMORY CELL STORAGE STATE

(75) Inventors: HAO MENG, Singapore (SG); Guchang Han, Singapore (SG); Li Wang, Singapore (SG); Bo Liu, Singapore (SG)

(73) Assignee: Agency for Science, Technology and Research

(21) Appl. No.: 12/876,633

(22) Filed: Sep. 7, 2010

(30) Foreign Application Priority Data
Sep. 7, 2009 (SG) 200905930-4

(51) Int. Cl. G11C 11/16

(52) U.S. Cl. 365/158

(57) ABSTRACT

A memory cell arrangement is provided including a magnetoresistive memory cell; and a frequency determiner configured to determine a spin precession frequency provided by the magnetoresistive memory cell; and a storage state determiner configured to determine the magnetoresistive memory cell storage state of the magnetoresistive memory cell based on the determined spin precession frequency.

### CROSS-REFERENCE TO RELATED APPLICATION

This application claims priority to Singapore Patent Application No. 200905930-4, which was filed Sep. 7, 2009, and is incorporated herein by reference in its entirety.

### TECHNICAL FIELD

Various embodiments relate generally to memory cell arrangements, to a memory cell reader, and to a method for determining a memory cell storage state.

### BACKGROUND

In 2007, the world-wide Hard Disk Drive (HDD) industry distributed more than 500 million HDD units and factory revenues reached 32 billion US dollars. Such strong demand for HDD units comes not only from traditional PC and enterprise storage markets but also from new storage demands such as entertainment, digital video storage and mobile devices. Low cost over storage capacity of HDD units is a key factor behind the huge numbers of shipments and demands. The HDD industry roadmap predicts a 40% annual areal density growth to maintain its domination in the storage market. Technically, areal density growth requires higher linear and track densities. Thus, data playback requires reader geometry size to shrink accordingly in order to detect a magnetic signal. However, smaller reader size often results in higher resistance and impedance mismatch problems, which are serious issues for high speed data transfer. In addition, noise from thermal fluctuation and spin momentum torque are other effects concerned with reader shrinking. To meet the areal density requirements beyond 2 Tbit/in², future reader designs should target performances characterised by low resistance area product (RA<0.1 Ωm²) and high magnetoresistance signal (MR>15%).

Current commercial readers adopt MgO based magnetic tunneling junctions (MTJ), which produce large tunneling magnetoresistance (TMR) signals (TMR 30˜70%) with relatively low RA (0.4 to 1 Ωμm²). However, MTJ readers are not expected to exceed 1 Tbit/in² as TMR signals significantly decay with decreasing RA.

Current-perpendicular-to-plane (CPP) giant magnetoresistance (GMR) readers, on the other hand, provide an additional option for high areal density recording. CPP-GMR readers using metal spin valve films have a much lower RA value. One of the challenges facing CPP-GMR technology is low measured GMR signals (GMR<2%) due to high parasitic resistance from the layers in the CPP-GMR reader (RₚₐᵣₐA˜30 to 50 mΩμm², ΔRA only ˜1-2 mΩμm²). Although many alternative CPP spin valve structures such as half-metal spin valves and current-confined-path (CCP) spin valves have been proposed and demonstrated, the achieved GMR versus RA performance does not satisfy the requirement for future high areal density recording. In TMRC 2007, HGST announced ˜17% GMR signal with RA˜0.2 Ωμm² in a CCP-CPP-GMR head. Although the GMR signal reported was greatly improved compared with the previous reports, lower RA values are still needed to achieve areal densities up to 2 Tbit/in² and beyond.

Another challenge for CCP GMR heads is uniformity control, which becomes a more serious concern with shrinking reader size. Progress in half-metal spin valve heads is relatively slow due to difficulties in the fabrication of GMR films. Band matching between the reference layer and spacer free layer is very critical to obtaining high spin polarization and therefore high GMR signal according to theoretical calculation. Current thin film sputtering techniques cannot avoid defects in the GMR thin film stack and this results in band mismatch. Further, although high spin polarization ratios have been observed in bulk half metal material, it is very difficult to repeat the same behavior with thin films due to poor surface spin polarization. The reported GMR signal of half metal spin valves with metal spacers is normally less than 3% at room temperature.

In addition to the issues concerning magnetoresistive signals and RA values, magnetic noise induced by spin momentum transfer (SMT) is another major concern with reader size shrinking. In GMR heads, a small sensing current (Iₛₑₙₛ) is used to detect the magnetization status of the free layer. However, the magnetization status of the free layer can be disturbed by Iₛₑₙₛ due to the SMT effect. The SMT noise can be ignored when the GMR reader is large; however, such magnetization fluctuations becomes more severe with shrinking GMR readers because the sensing current density is increased.

The HDD industry has directed more resources towards developing GMR readers with low RA and high magnetoresistive signals. Although encouraging progress has been achieved in recent years, current reader technology for detecting magnetoresistive signals will eventually face its limitations in increasing areal density.

To meet the requirement of 40% annual areal density growth rate, a new reader sensor design for magnetic signal detection is proposed. An areal density of 10 Tb/in² areal density with approximate bit size 6×11 nm² is targeted. To meet the areal density, a linear density of up to 4000 kbit/in, a track density of up to 2500 kt/in (linear density will increase with low track density) and a read bit transfer rate of up to 2 Gbit/s is required. Such high bit transfer rate corresponds to high frequency reader response, which is proportional to 1/RC (product of resistance and capacitance). The HDD roadmap has predicted resistance area product, RA˜0.1 Ωμm² for 1 Tb/in² areal density with bit transfer rates of approximately 1 Gbit/s. Thus, targeted data transfer rates of 2 Gbit/s for 10 Tb/in² areal density ought to achieve an RA value of approximately 0.026 Ωμm². All reader sensor designs under development are far below this specification requirement.

New magnetic sensing methods should therefore be in the roadmap to provide a solid base for continual areal density growth. The present disclosure generally relates to a signal detection method for magnetic recording, and magnetic field detection methods on magnetic recording media, e.g. to a perpendicular magnetic recording media.

### SUMMARY

An embodiment is a memory cell arrangement including a magnetoresistive memory cell; and a frequency determiner configured to determine a spin precession frequency provided by the magnetoresistive memory cell; and a storage state determiner configured to determine the magnetoresistive memory cell storage state of the magnetoresistive memory cell based on the determined spin precession frequency.

Another embodiment is a memory cell reader, including a frequency determiner configured to determine a spin precession frequency provided by a magnetoresistive memory cell; and a storage state determiner configured to determine the magnetoresistive memory cell storage state of the magnetoresistive memory cell based on the determined spin precession frequency.

Another embodiment is a memory cell arrangement, including a magnetic memory cell; a magnetoresistive cell configured to generate a spin precession frequency under a magnetic field from the magnetic memory cell; a frequency determiner configured to determine a spin precession frequency provided by the magnetoresistive cell; and a storage state determiner configured to determine the magnetic memory cell storage state based on the determined spin precession frequency.

Another embodiment is a memory cell arrangement, including a magnetoresistive memory cell array which may include a plurality of magnetoresistive memory cells; and a frequency determiner configured to determine a spin precession frequency provided by one magnetoresistive memory cell of the plurality of magnetoresistive memory cells; and a storage state determiner configured to determine the magnetoresistive memory cell storage state of the magnetoresistive memory cell based on the determined spin precession frequency.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a memory cell arrangement in accordance with one embodiment;

FIG. 2 shows a memory cell arrangement in accordance with an alternative embodiment;

FIG. 3 shows a memory cell reader in accordance with an embodiment;

FIG. 4 shows a memory cell arrangement which may include a magnetoresistive memory cell array in accordance with an embodiment;

FIG. 5 shows a memory cell arrangement which may include a magnetoresistive memory cell array in accordance with an alternative embodiment;

FIG. 6 shows a method for determining a memory cell storage state of a magnetoresistive memory cell in accordance with various embodiments;

FIG. 7 shows an illustration of spin torque transfer effect in nanomagnetic devices in accordance with various embodiments;

FIG. 8 shows an illustration of spin precession under applied DC current due to spin torque τ in accordance with various embodiments;

FIG. 9A shows an illustration of a spin precession mode excited by a biased DC current through the spin torque transfer effect (STT) effect in accordance with various embodiments;

FIG. 9B shows an illustration of spin precession frequency excited by a biased DC current through the spin torque transfer effect (STT) effect in accordance with various embodiments;

FIG. 10 shows a graph of spin oscillation frequency versus media field in accordance with various embodiments;

FIG. 11A shows a magnetoresistive memory cell stack configuration in accordance with various embodiments;

FIG. 11B shows a magnetoresistive memory cell stack configuration in accordance with various embodiments;

FIG. 11C shows a magnetoresistive memory cell stack configuration in accordance with various embodiments.

FIG. 12 shows a memory cell arrangement in accordance with an embodiment for determining a magnetic memory cell storage state.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various embodiments provide alternative methods for detecting magnetic field signals, which need not rely on the GMR values of the magnetic reader sensors. In current-perpendicular-to-plane (CPP) giant magnetoresistance (GMR) readers, for example, a DC current is typically applied through the CPP direction in a GMR element. Due to the spin torque transfer (STT) effect, applying a DC bias current through the sensor excites free layer spin precession at a fixed frequency f₀, which depends on the magnetic field. When a DC current is applied through the CPP direction in a GMR reader, the DC current excites free layer spin precession at a fixed frequency f₀ due to the STT effect. The fixed frequency f₀ may depend on the effective field (H_{eff}) of the free layer. When the GMR element flies on a magnetic media, H_{eff} is changed due to a magnetic field (Hₘ). For example, H_{eff} may be changed in such a way that H_{eff}=H_{eff0}+Hₘ at bit “0” and H_{eff}=H_{eff0}−Hₘ at bit “1”, where H_{eff0} is the effective field without an external media field.

The spin precession frequency induced by the DC current may be f₁ at bit “0” and f₂ at bit “1”. The spin precession frequency difference between different bit types may be expressed as f₁−f₂.

The reader sensor according to various embodiments may detect free layer spin precession frequency instead of linear changes in GMR.

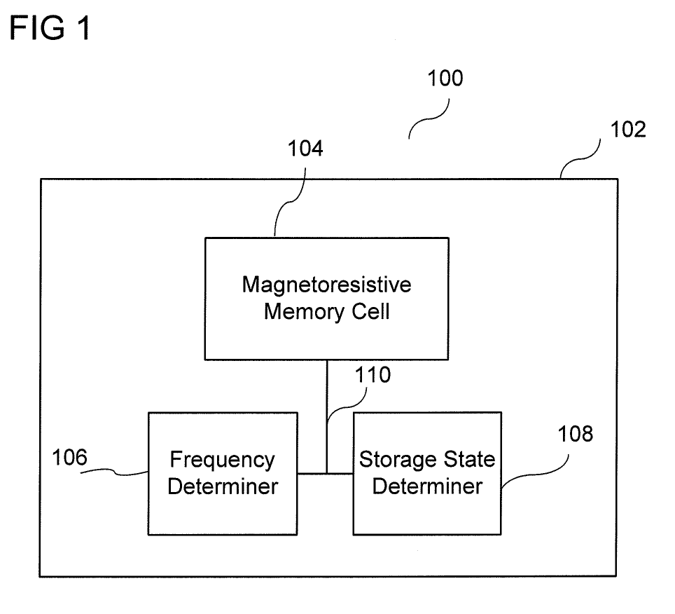

FIG. 1 shows an illustration 100 of a memory cell arrangement in accordance with an embodiment. In this embodiment, a memory cell arrangement 102 includes a magnetoresistive memory cell 104, and a frequency determiner 106 configured to determine a spin precession frequency provided by the magnetoresistive memory cell 104, and a storage state determiner 108 configured to determine the magnetoresistive memory cell storage state of the magnetoresistive memory cell 104 based on the determined spin precession frequency. The magnetoresistive memory cell 104 may be connected to the frequency determiner 106 and the storage state determiner 108 via a connection 110. Frequency determiner 106 and the storage state determiner 108 may be connected via the connection 110 to allow the storage state determiner 108 to determine the magnetoresistive memory cell storage state of the magnetoresistive memory cell 104 based on the determined spin precession frequency.

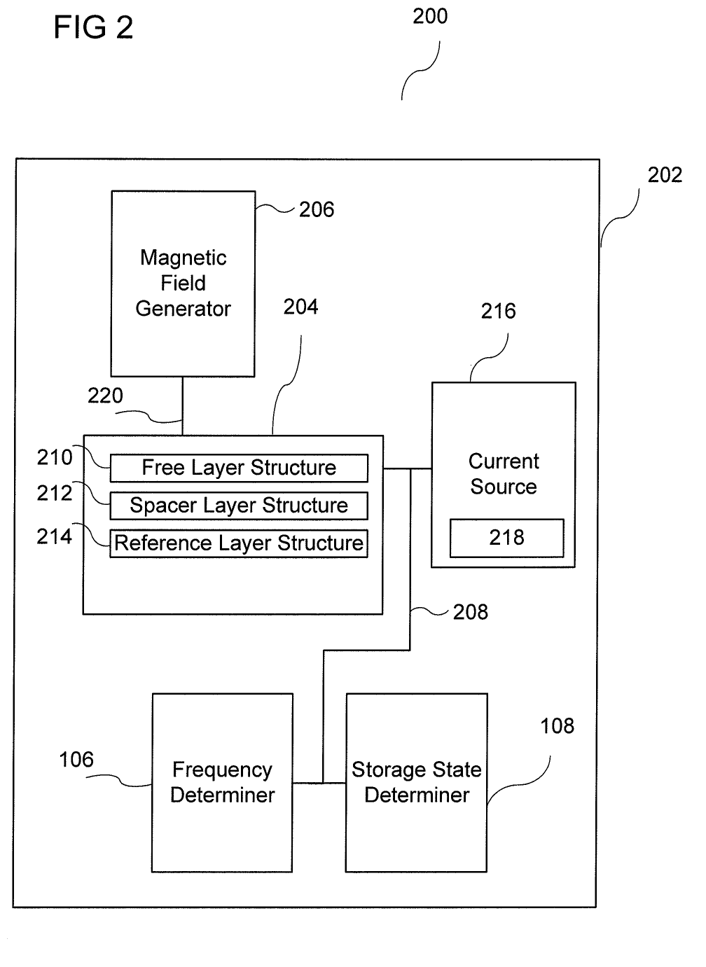

FIG. 2 shows an illustration 200 of a memory cell arrangement in accordance with an alternative exemplary embodiment. In this embodiment, a memory cell arrangement 202 may include a magnetoresistive memory cell 204, and a frequency determiner 106 configured to determine a spin precession frequency provided by the magnetoresistive memory cell 204, and a storage state determiner 108 configured to determine the magnetoresistive memory cell storage state of the magnetoresistive memory cell 204 based on the determined spin precession frequency.

The memory cell arrangement 202 may further include a current source 216 coupled to the magnetoresistive memory cell 204 to provide a current to the magnetoresistive memory cell. The current source 216 of memory cell arrangement 202 may include comprises a DC current source to provide a DC current to the magnetoresistive memory cell 204. The magnetoresistive memory cell 204 of memory cell arrangement 202 may include a free layer structure 210, a spacer layer structure 212 and a reference layer structure 214. The frequency determiner 106 of memory cell arrangement 202 may further include a spectrum analyzer.

In another exemplary embodiment, storage state determiner 108 of memory cell arrangement 202 may be configured to determine the magnetoresistive memory cell storage state of the magnetoresistive memory cell 204 based on a comparison of the determined spin precession frequency with at least one of a first predefined spin precession frequency associated with a first magnetoresistive memory cell storage state and a second predefined spin precession frequency associated with a second magnetoresistive memory cell storage state.

In another exemplary embodiment, the storage state determiner 108 of memory cell arrangement 202 may be configured to determine the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state. Memory cell arrangement 202 may further include a magnetic field generator 206 configured to apply an external magnetic field to the magnetoresistive memory cell. The magnetic field generator 206 may be configured to apply a fixed external magnetic field to the magnetoresistive memory cell 204. Magnetoresistive memory cell 204 may be connected to frequency determiner 106 and a storage state determiner 108 via connection means 208. Current source 216 may include a DC current source 218 to provide a DC current for example, in a CPP direction, to magnetoresistive memory cell 204.

One of the effects of the described embodiments lies in that because the magnetic field signal detection method determines spin precession frequency instead of conventional linear GMR signals, the magnetoresistive memory cell does not require an anti-ferromagnetic (AFM) layer, which has the effect of narrowing shield-to-shield spacing in a the magnetoresistive memory cell.

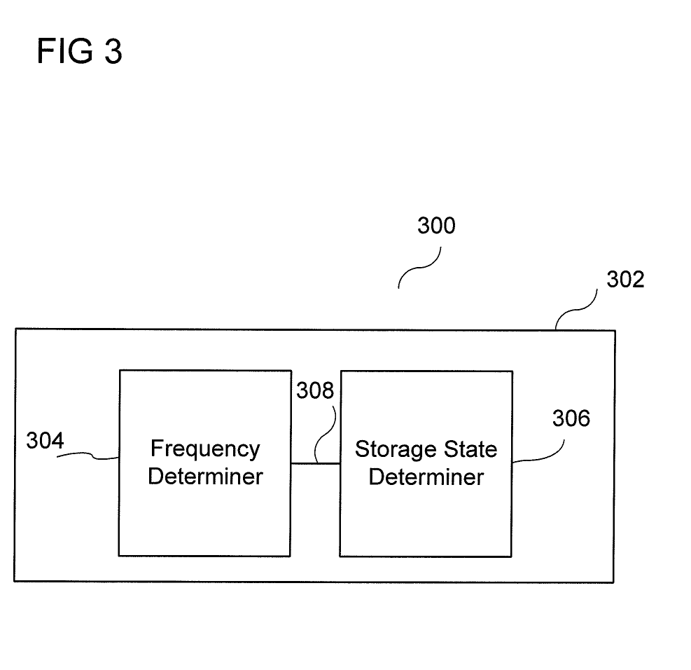

FIG. 3 shows an illustration 300 of a memory cell reader 302 in accordance with an embodiment. In this embodiment, the memory cell reader 302 includes frequency determiner 304 configured to determine a spin precession frequency provided by a magnetoresistive memory cell; and a storage state determiner 306 configured to determine the magnetoresistive memory cell storage state of the magnetoresistive memory cell based on the determined spin precession frequency. Frequency determiner 304 may be connected via connection means 308 to storage state determiner 306. The frequency determiner 304 of memory cell reader 302 may further include a spectrum analyzer. In an exemplary embodiment, storage state determiner 306 may be configured to determine the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state.

In another exemplary embodiment, storage state determiner 306 may be configured to determine the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state.

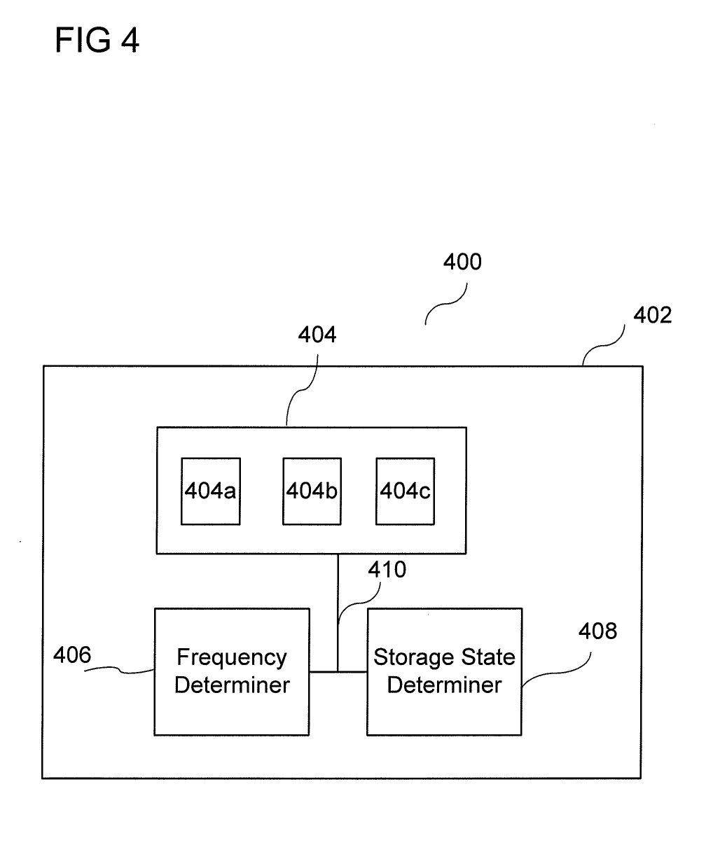

FIG. 4 shows an illustration 400 of a memory cell arrangement 402 which may include a magnetoresistive memory cell array 404 in accordance with an embodiment. In this embodiment, memory cell arrangement 402 may include a magnetoresistive memory cell array 404 which may include a plurality of magnetoresistive memory cells 404a, 404b, 404c, and a frequency determiner 406 configured to determine a spin precession frequency provided by one magnetoresistive memory cell of the plurality of magnetoresistive memory cells 404a, 404b, 404c; and a storage state determiner 408 configured to determine the magnetoresistive memory cell storage state of the magnetoresistive memory cell based on the determined spin precession frequency.

In an exemplary embodiment, memory cell arrangement 402 may include a magnetoresistive memory cell array 404 which may be connected to a frequency determiner 406 and storage state determiner 408 via coupling connection 410. Although only three magnetoresistive memory cells are shown within the magnetoresistive memory cell array 404 in FIG. 4, the number of magnetoresistive memory cells within magnetoresistive memory cell array 404 is not limited to three and may contain two, three or more than three.

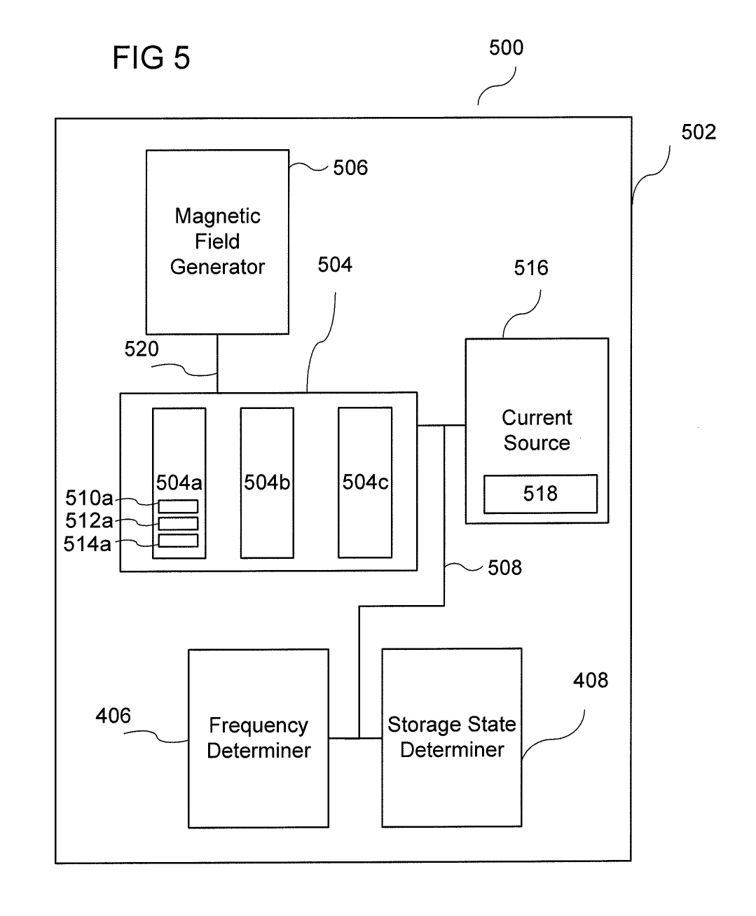

FIG. 5 shows an illustration 500 of a memory cell arrangement which may include a magnetoresistive memory cell array 504 in accordance with an alternative embodiment. In this embodiment, memory cell arrangement 502 may include a magnetoresistive memory cell array 504 which may include a plurality of magnetoresistive memory cells 504a, 504b, 504c, and a frequency determiner 406 configured to determine a spin precession frequency provided by one magnetoresistive memory cell of the plurality of magnetoresistive memory cells 504a, 504b, 504c; and a storage state determiner 408 configured to determine the magnetoresistive memory cell storage state of the magnetoresistive memory cell based on the determined spin precession frequency.

In an exemplary embodiment, memory cell arrangement 502 may include a magnetoresistive memory cell array 504 which may be connected to a frequency determiner 406 and storage state determiner 408 via coupling connection 508. Although only three magnetoresistive memory cells are shown within the magnetoresistive memory cell array 504 in FIG. 5, the number of magnetoresistive memory cells within magnetoresistive memory cell array 504 is not limited to three and may contain two, three or more than three.

In an embodiment, memory cell arrangement 502 may include a current source 516 coupled to at least one magnetoresistive memory cell of the plurality of magnetoresistive memory cells to provide a current to the magnetoresistive memory cell. Current source 516 may include a DC current source to provide a DC current to the magnetoresistive memory cell. In another exemplary embodiment, at least one magnetoresistive memory cell of the plurality of magnetoresistive memory cells 504a 504b 504c of memory cell arrangement 502 may include a free layer structure 510a, a spacer layer structure 512a and a reference layer structure 514a. Although free layer structure 510a, spacer layer structure 512a and reference layer structure 514a are only shown in magnetoresistive memory cells 504a, the presence of a free layer structure, a spacer layer structure and a reference layer structure is not limited to being present only in magnetoresistive memory cell 504a but may be present in a plurality of magnetoresistive memory cells for example 504b and 504c. The frequency determiner 406 of memory cell arrangement 502 may further include a spectrum analyzer.

In another embodiment, storage state determiner 408 of memory cell arrangement 502 may be configured to determine the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state.

In another embodiment, storage state determiner 408 of memory cell arrangement 502 may be configured to determine the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state. In another exemplary embodiment, the memory cell arrangement 502 may further include a magnetic field generator 506 configured to apply an external magnetic field to at least one magnetoresistive memory cell of the plurality of magnetoresistive memory cells. In another exemplary embodiment, the magnetic field generator 506 may be configured to apply a fixed external magnetic field to the at least one magnetoresistive memory cell of the plurality of magnetoresistive memory cells.

In another embodiment, the spin precession frequency provided by one magnetoresistive memory cell of the plurality of magnetoresistive memory cells 504a, 504b, 504c may be determined by using a spectrum analyzer as a frequency determiner 406 through a coplanar circuit design, which is already widely used in wireless communication devices. Current source 516 may include a DC current source 518 to provide a DC current for example, in a CPP direction, to at least one magnetoresistive memory cell of the plurality of magnetoresistive memory cells 504a, 504b, 504c.

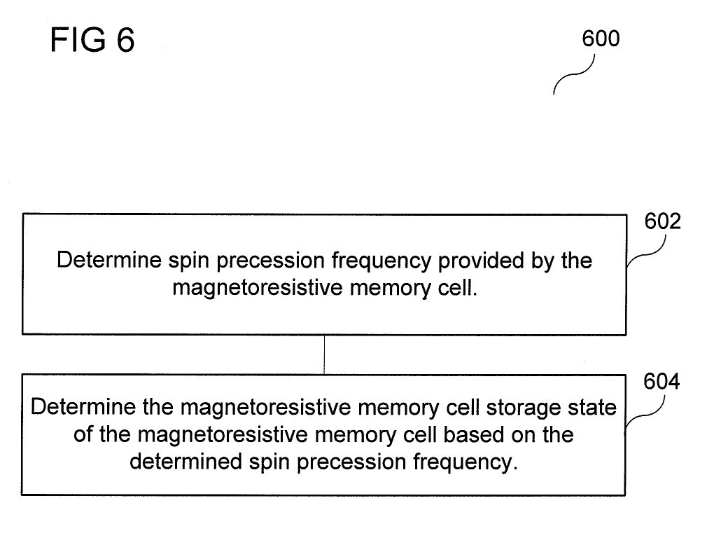

FIG. 6 shows a method 600 for determining a memory cell storage state of a magnetoresistive memory cell in accordance with an embodiment. In 602, the spin precession frequency provided by the magnetoresistive memory cell is determined. In 604, the magnetoresistive memory cell storage state of the magnetoresistive memory cell is determined based on the determined spin precession frequency. In another exemplary embodiment, method 600 may include providing a current to the magnetoresistive memory cell. Providing the current to the magnetoresistive memory cell may include providing a DC current to the magnetoresistive memory cell. The spin precession frequency of method 600 may be determined using a spectrum analyzer. The method 600 may include determining the memory cell storage state which may include determining the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state. The method 600 may include determining the memory cell storage state which may include determining the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state. The method 600 may include applying an external magnetic field to the magnetoresistive memory cell. The method 600 may include applying an external magnetic field to the magnetoresistive memory cell which may include applying a fixed external magnetic field to the magnetoresistive memory cell.

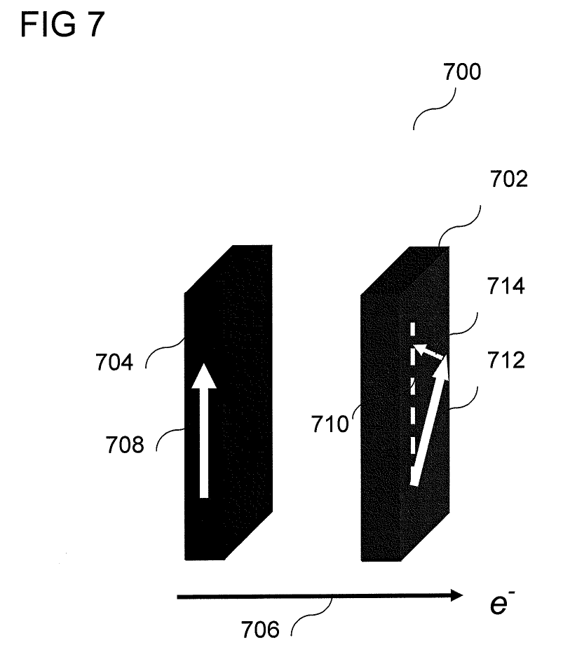

FIG. 7 shows an illustration 700 of the spin torque transfer effect in nanomagnetic devices in accordance with one exemplary embodiment. In this exemplary embodiment, ferromagnetic (FM) layers 704 and 702 may form a FM/non-magnetic/FM structure. Current applied along CPP direction 706 may induce spin torque inside a FM layer. The applied current may be polarized (spin up) when flowing from a first FM layer 704 to a second FM layer 702. If the first FM layer 704 and second FM layer 702 have different magnetization directions 708, 712, the spin polarized electron current may interact with local spins inside second FM layer 702 through exchange coupling. Such spin torque may try to align the local spin direction 714 to the local spin direction in first FM layer 710. Since spin torque may be proportional to the spin polarized current, the magnetization of first FM layer 704 may be switched by the spin torque if the spin polarized current is high enough.

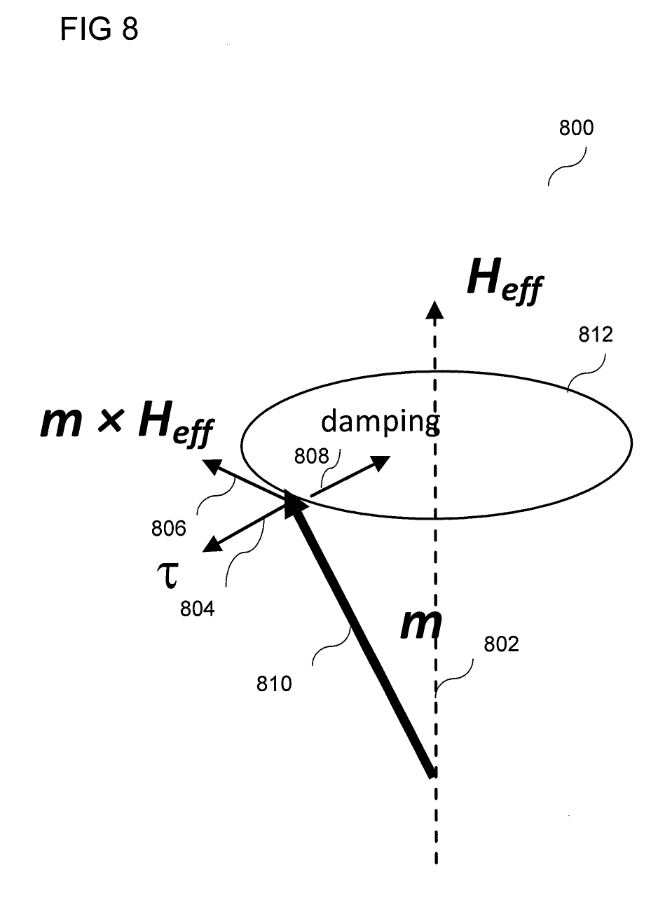

FIG. 8 shows an illustration 800 of spin precession under an applied DC current due to spin torque τ in accordance with one exemplary embodiment of the invention.

The modified Landau-Lifshitz-Gilbert equation with spin torque may be determined by

$$\frac{d \hat{m}}{d t} = \hat{γ m} \times {\hat{H}}_{eff} + α \hat{m} \times \frac{d \hat{m}}{d t} + {γα}_{j} \hat{m} \times ( \hat{m} \times \hat{M} )$$

where γ may be the gyromagnetic ratio and a may be the damping parameter, H_{eff} may be the effective magnetic field, αⱼ may be proportional to applied current amplitude and spin polarization ratio, m (M) may be the magnetization vector of free (fixed) layer. The polarization ratio may depend on material properties of first FM layer 704.

In this exemplary embodiment, a traceable path of the precessional motion of a particle is illustrated by oscillation path 812. From the modified Landau-Lifshitz-Gilbert equation the time-dependent precessional motion may depend on the cross product result 806 of the magnetization vector of the free layer 810 and the vector of effective magnetic field H_{eff}. Directions of spin torque τ 804 and damping torque 806 are also illustrated in FIG. 8.

Calculations suggest that the spins may start to precess at high frequency even at small applied DC current. For small angle elliptical precession of a thin-film ferromagnet, precession frequency f may be determined by

$$f \approx \frac{γ}{2 π} \sqrt{( {H}_{app} + {H}_{k} ) ( {H}_{app} + {H}_{k} + 4 π {M}_{effe} )}$$

where M_{effe} may be the effective saturation magnetization of free layer, Hₐₚₚ may be the applied magnetic field. Hₖ may be the anisotropy field. As applied field Hₐₚₚ may change either in direction or amplitude, the precession frequency f may change accordingly.

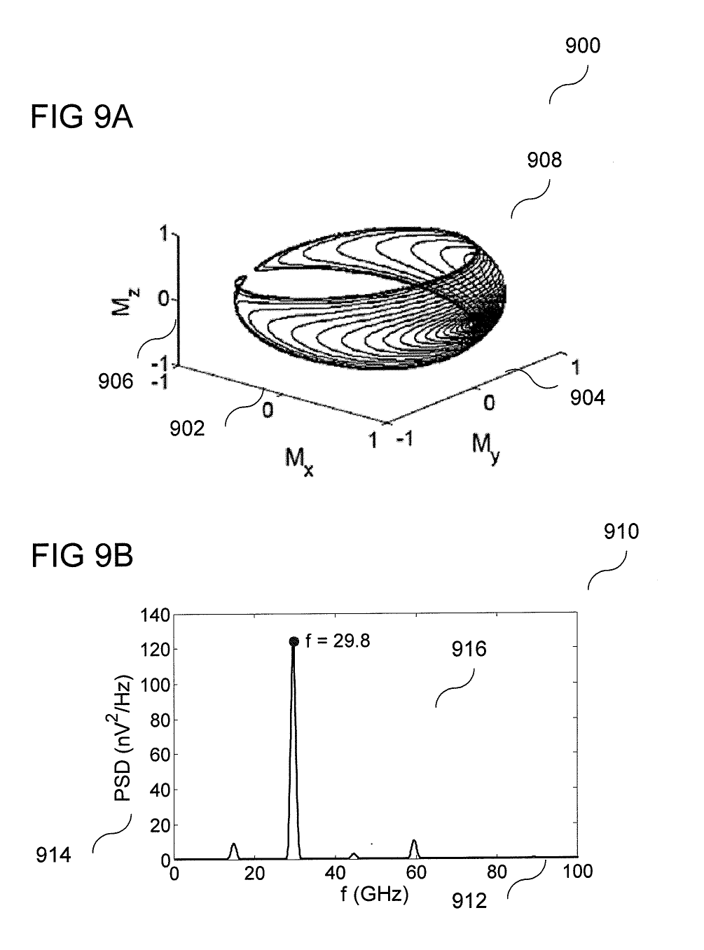

FIG. 9A shows an illustration 900 of a spin precession mode 908 excited by a biased DC current through the STT effect in accordance with an embodiment. The illustration shows that a spin precession mode 908 may be excited by a biased DC current (4 mA) through the STT effect.

FIG. 9B shows an illustration 910 of spin precession frequency 916 which may be excited by a biased DC current through the spin torque transfer effect (STT) effect in accordance with an embodiment. The spin precession frequency may be fixed (for example at f=29.8 GHz in FIG. 9B) when the bias current and magnetic field are fixed. The three smaller peaks in FIG. 9B may be from harmonic frequencies and may be filtered. With fixed bias current and external magnetic field, the spin precession frequency may follow only one mode (FIG. 9A) and only one frequency (FIG. 9B).

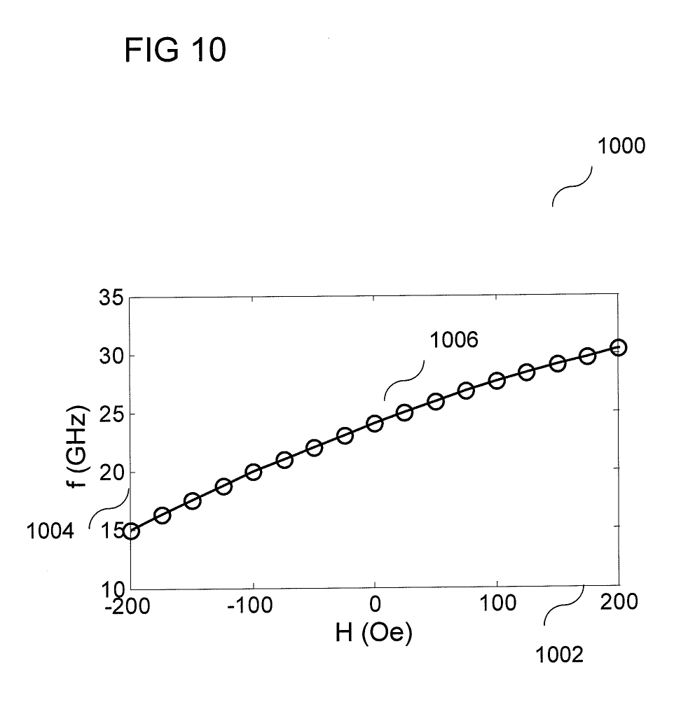

FIG. 10 shows a graph 100 of spin oscillation frequencies versus media field in accordance to one aspect of the invention. In this exemplary embodiment, preliminary results of spin precession frequency versus media field are shown for the case where a DC current may be applied in a CPP direction in a GMR element. The graph 1006 shows that when magnetic field increases from −200 Oe to 200 Oe, the spin precession frequency may shift linearly from 15 GHz to 30 GHz.

As typical magnetic fields from magnetic media at the memory cell reader flying height range from approximately −200 Oe to +200 Oe, spin precession at spin precession frequencies from 15 GHz to 30 GHz may be present in this range. A recording bit “0” at −200 Oe and recording bit “1” at 200 Oe, may result in a spin precession frequency change Δf of up to 15 GHz, which is large and easily measurable. The spin precession frequency may be further increased by tuning the material of the free layer material and the bias field.

These results present significant improvements over traditional GMR (or TMR) memory cell readers. Traditional GMR (or TMR) memory cell readers use a different detection scheme. For example, traditionally a free layer may be pre-set to be perpendicular to a reference layer through a bias field. Bit “0” or “1” in the media field induces a magnetic field on free layer and force it to rotate from its original position. Since GMR depends on the relative angle between free and reference layers, bit “0” and “1” in the media field induces a GMR difference (AGMR) due to free layer rotation. This detection method is limited by the GMR value of the element (for example, ΔTMR<20%, ΔGMR<5%), which is much smaller than the proposed method (Δf≈100%).

In exemplary embodiments of this invention, the memory cell reader may determine the spin precession frequency so the requirement for high GMR output is no longer as critical a factor in reader design in this invention as it is in traditional GMR (or TMR) reader designs using traditional GMR detection schemes.

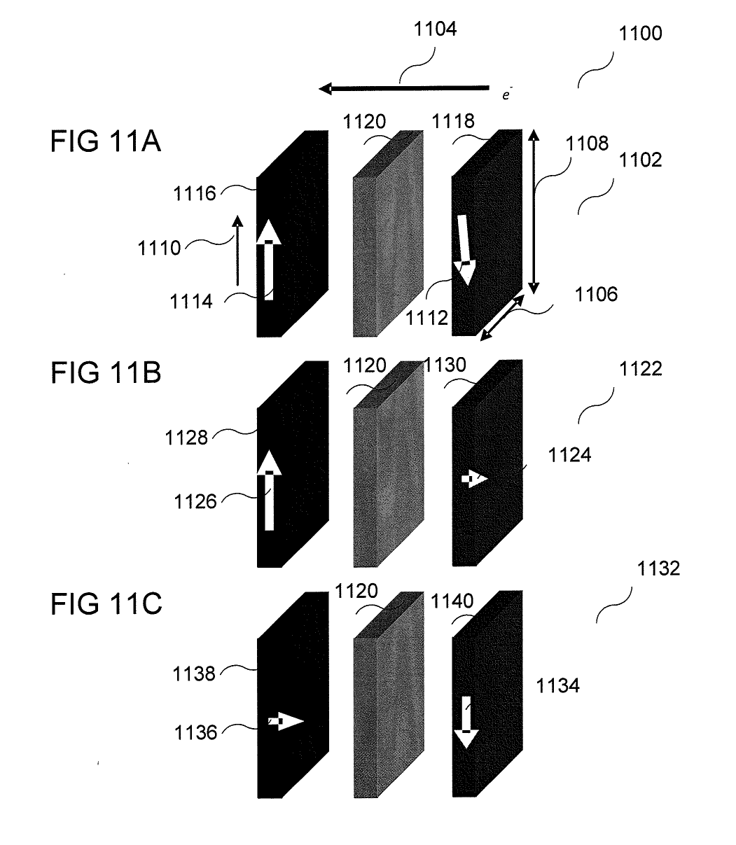

FIG. 11A shows an illustration 1100 of a magnetoresistive memory cell stack configuration according to one exemplary embodiment of the invention. In this exemplary embodiment, a stack configuration 1102 of a reader sensor may include a seed layer (not shown), a tri-layer spin valve GMR structure (reference layer-spacer layer-free layer 1118-1120-1116), sandwiched by top and bottom electrodes (not shown). The material of the spacer layer may be but is not limited to Cu. The current may flow along the CPP direction 1104. The dimensions of each layer the tri-layer spin valve GMR structure may be defined by a stripe height 1108 and track width 1106. The free layer 1116 may border an air bearing surface 1110. The magnetization direction of the free layer 1114 may be nearly antiparallel to the magnetization direction of the reference layer 1112. The media field may lie along the direction of the free layer magnetization. Electron flow from reference layer to the free layer and excited spin torque may drive the free layer precession at a frequency f₀, which may vary depending on the media field.

Materials of the reference layers and free layers may be but are not limited by common material candidates, such as CoFe, NiFe. The stack thicknessess may be significantly reduced to meet the narrow shield-to-shield-spacing (SSS) requirements.

FIG. 11B shows an illustration 1122 of a magnetoresistive memory cell stack configuration according to an alternative exemplary embodiment of the invention. In this exemplary embodiment, a stack configuration 1122 of a reader sensor may include reference layer-spacer layer-free layer 1130-1120-1128. The magnetization direction of the free layer 1126 may be perpendicular to the magnetization direction of the reference layer 1124. The media field may lie along the direction of the free layer magnetization. The reference layer 1130 may have out-of-plane magnetization. Hence, the magnetization of the free layer or reference layer may be out-of-plane with perpendicular anisotropy. The effect of the magnetization direction of the free layer 1126 being perpendicular to the magnetization direction of the reference layer 1124 may result in an increase in the spin torque effect. The reference layer may be of a high anisotropy Kᵤ material, which is more stable under media field. The material candidates of the free layer and reference layer may be but or not limited to CoPt/FePt and high Kᵤ materials. Other possible material and structure candidates can be but are not limited to multilayer structures such as Co/Ni, Co/Pt.

FIG. 11C shows an illustration 1132 of a magnetoresistive memory cell stack configuration according to another alternative exemplary embodiment of the invention. In this exemplary embodiment, a stack configuration 1132 of a reader sensor may include reference layer-spacer layer-free layer 1140-1120-1138. The free layer magnetization direction 1136 may be out-of-plane and perpendicular to reference layer magnetization direction 1134 resulting in an increase in the spin torque effect. As the media field may be perpendicular to the direction of the free layer magnetization 1136, the field dependence of spin precession frequency may not be linear. Possible material and structure candidates can be but are not limited to CoPt, FePt or multilayer structures such as Co/Ni, Co/Pt.

Traditonal reader sensor structures using traditional GMR value detection schemes include an anti-ferromagnetic (AFM) layer such as IrMn, for example, to fix magnetization of the reference layer. The typical AFM layer thickness is typically around 6-7 nm to ensure pinning effect and thermal stability. Such thickness almost exceeds the 12 nm SSS budget for 10 Tbit/in² areal density and seriously decays the GMR effect due to its large resistance ratio within the whole stack structure. As the exemplary embodiments of FIGS. 11A, 11B and 11C may have the AFM layer removed, SSS values as small as 12 nm can be achieved. The free layer need not be biased to obtain better sensitivity as in traditional reader sensors and thus allowing reader sensor structures to be simplified due to magnetic hard bias free design.

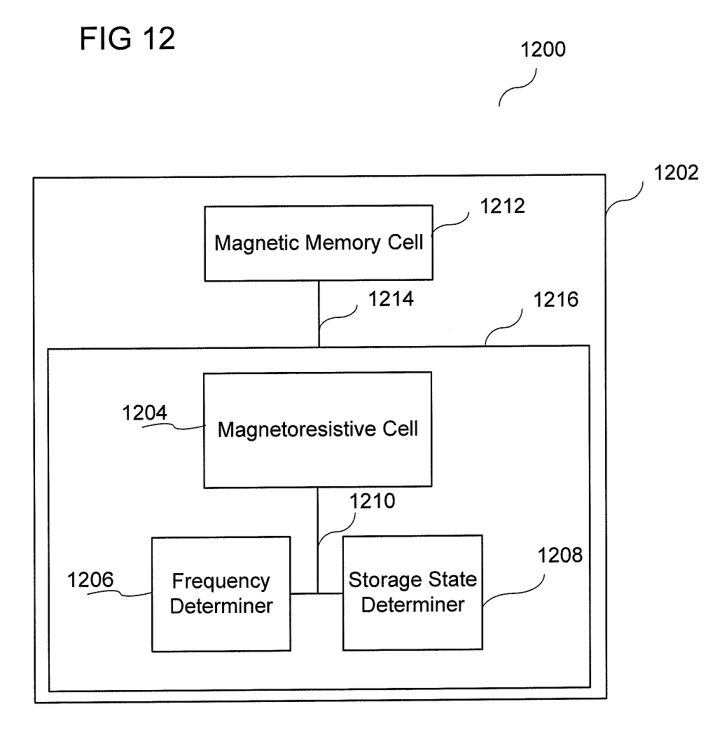

FIG. 12 shows an illustration 1200 of a memory cell arrangement in accordance with an embodiment. In this embodiment, a memory cell arrangement 1202, includes a magnetic memory cell 1212, a magnetoresistive cell 1204 configured to generate a spin precession frequency under a magnetic field from the magnetic memory cell 1212, a frequency determiner 1206 configured to determine a spin precession frequency provided by the magnetoresistive cell 1204, and a storage state determiner 1208 configured to determine the magnetic memory cell storage state based on the determined spin precession frequency. In this embodiment, a magnetoresistive cell reader arrangement 1216 of memory cell arrangement 1202 may detect the storage state of magnetic memory cell 1212. Frequency determiner 1206 may be connected via connection means 1210 to storage state determiner 1208. Magnetic memory cell 1212 may be connected to magnetoresistive cell reader arrangement 1216 of memory cell arrangement 1202 via connection means 1214. The frequency determiner 1206 of memory cell arrangement 1202 may further include a spectrum analyzer. In an exemplary embodiment, storage state determiner 1208 may be configured to determine the magnetic memory cell storage state of the magnetic memory cell based on a comparison of the determined spin precession frequency with at least one of a first predefined spin precession frequency associated with a first magnetic memory cell storage state and a second predefined spin precession frequency associated with a second magnetic memory cell storage state.

In another exemplary embodiment, storage state determiner 1208 may be configured to determine the magnetic memory cell storage state of the magnetic memory cell based on a comparison of the determined spin precession frequency with a frequency threshold, which is arranged between a first predefined spin precession frequency associated with a first magnetic memory cell storage state and a second predefined spin precession frequency associated with a second magnetic memory cell storage state.

Since spin precession frequency signal-to-noise ratio relies on the frequency difference instead of GMR value, very low values of resistance×area (RA) of the GMR element and narrow shield-to-shield spacing are attainable. These factors are very critical for high density magnetic recording. In addition, there is negligible noise from spin torque transfer, which is a big problem associated with shrinking down of reading element in traditional GMR detection schemes. Exemplary embodiments of the invention thus achieve the following effects.

1. Small shield-to-shield spacing (SSS): The simple GMR structure does not require a synthetic anti-ferromagnetic (SAF) or anti-ferromagnetic AFM pinned structure. Hard reference layers used in the preferred exemplary embodiments makes it possible to remove anti-ferromagnetic (AFM) layer. This means that the SSS distance may be greatly reduced to 9 nm or less, resulting in a four fold larger linearly density compared with present technology.

2. No spin torque noise: The spin torque transfer (STT) effect is measured as a frequency determined signal source instead of noise. This is a big advantage for small sensor.

3. Ultra-low RA: As memory cell readers of exemplary embodiments of the invention typically use an all metal CPP GMR structure, resistance×area RA values below 0.05 Ωμm² are typically achieved. Therefore, memory cell readers according to exemplary embodiments of the invention are not no longer restrained by the impedance limit of smaller reader sensor designs.

4. No need for high GMR value: As memory cell readers of exemplary embodiments of the invention use the frequency spectrum (from several GHz to 20 GHz) to detect media field, a high GMR output is not as critical as a traditional reader design even though the GMR effect may be used to generate a voltage signal. The required signal-to-noise ratio does not depend on GMR value but on frequency change Δf, providing a suitable solution for 10 Tbit/in² or even higher recording technology.

5. Low noise and high signal-to-noise ratio (SNR): As memory cell readers of exemplary embodiments of the invention function at high frequency, noise from thermal magnetization fluctuation, Johnson noise/shot noise can be filtered as much as possible. Compared with STT induced signals, the noise voltage output is much lower. In addition, Johnson noise is naturally reduced at low RA value.

6. Possible elimination of hard biasing: As the reference layer and free layer may be parallel or anti-parallel to air bearing surface (ABS), a hard bias permanent magnet is not required to set free layer direction, resulting in a great process simplification magnetic cell reader design.

Aspects of various embodiments propose magnetic field detection methods to solve issues of RA, output signal and spin torque noise. Small shield-to-shield spacing without requiring an AFM layer and high speed signal detection free from spin torque noise may be attained.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A memory cell arrangement, comprising:
a magnetoresistive memory cell; and
a frequency determiner configured to determine a spin precession frequency provided by the magnetoresistive memory cell; and
a storage state determiner configured to determine the magnetoresistive memory cell storage state of the magnetoresistive memory cell based on the determined spin precession frequency.

2. The memory cell arrangement of claim 1, further comprising:
a current source coupled to the magnetoresistive memory cell to provide a current to the magnetoresistive memory cell.

3. The memory cell arrangement of claim 2,
wherein the current source comprises a DC current source to provide a DC current to the magnetoresistive memory cell.

4. The memory cell arrangement of claim 1,
wherein the memory cell comprises a free layer structure, a spacer layer structure and a reference layer structure.

5. The memory cell arrangement of claim 1,
wherein the frequency determiner comprises a spectrum analyzer.

6. The memory cell arrangement of claim 1,
wherein the storage state determiner is configured to determine the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state.

7. The memory cell arrangement of claim 1,
wherein the storage state determiner is configured to determine the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state.

8. The memory cell arrangement of claim 1, further comprising:
a magnetic field generator configured to apply an external magnetic field to the magnetoresistive memory cell.

9. The memory cell arrangement of claim 8,
wherein the magnetic field generator is configured to apply a fixed external magnetic field to the magnetoresistive memory cell.

10. A memory cell reader, comprising:
a frequency determiner configured to determine a spin precession frequency provided by a magnetoresistive memory cell; and
a storage state determiner configured to determine the magnetoresistive memory cell storage state of the magnetoresistive memory cell based on the determined spin precession frequency.

11. The memory cell reader of claim 10,
wherein the frequency determiner comprises a spectrum analyzer.

12. The memory cell reader of claim 10,
wherein the storage state determiner is configured to determine the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state.

13. The memory cell reader of claim 10,
wherein the storage state determiner is configured to determine the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state.

14. A memory cell arrangement, comprising:
a magnetic memory cell;
a magnetoresistive cell configured to generate a spin precession frequency under a magnetic field from the magnetic memory cell;
a frequency determiner configured to determine a spin precession frequency provided by the magnetoresistive cell; and
a storage state determiner configured to determine the magnetic memory cell storage state based on the determined spin precession frequency.

15. The memory cell arrangement of claim 14,
wherein the frequency determiner comprises a spectrum analyzer.

16. The memory cell arrangement of claim 14,
wherein the storage state determiner is configured to determine the magnetic memory cell storage state of the magnetic memory cell based on a comparison of the determined spin precession frequency with at least one of a first predefined spin precession frequency associated with a first magnetic memory cell storage state and a second predefined spin precession frequency associated with a second magnetic memory cell storage state.

17. The memory cell reader of claim 14,
wherein the storage state determiner is configured to determine the magnetic memory cell storage state of the magnetic memory cell based on a comparison of the determined spin precession frequency with a frequency threshold, which is arranged between a first predefined spin precession frequency associated with a first magnetic memory cell storage state and a second predefined spin precession frequency associated with a second magnetic memory cell storage state.

18. A memory cell arrangement, comprising:
a magnetoresistive memory cell array comprising a plurality of magnetoresistive memory cells; and
a frequency determiner configured to determine a spin precession frequency provided by one magnetoresistive memory cell of the plurality of magnetoresistive memory cells; and
a storage state determiner configured to determine the magnetoresistive memory cell storage state of the magnetoresistive memory cell based on the determined spin precession frequency.

19. The memory cell arrangement of claim 18, further comprising:
a current source coupled to at least one magnetoresistive memory cell of the plurality of magnetoresistive memory cells to provide a current to the magnetoresistive memory cell.

20. The memory cell arrangement of claim 19,
wherein the current source comprises a DC current source to provide a DC current to the magnetoresistive memory cell.

21. The memory cell arrangement of claim 18,
wherein at least one magnetoresistive memory cell of the plurality of magnetoresistive memory cells comprises a free layer structure, a spacer layer structure and a reference layer structure.

22. The memory cell arrangement of claim 18,
wherein the frequency determiner comprises a spectrum analyzer.

23. The memory cell arrangement of claim 18,
wherein the storage state determiner is configured to determine the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state.

24. The memory cell arrangement of claim 18,
wherein the storage state determiner is configured to determine the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state.

25. The memory cell arrangement of claim 18, further comprising:
a magnetic field generator configured to apply an external magnetic field to at least one magnetoresistive memory cell of the plurality of magnetoresistive memory cells.

26. The memory cell arrangement of claim 25,
wherein the magnetic field generator is configured to apply a fixed external magnetic field to the at least one magnetoresistive memory cell of the plurality of magnetoresistive memory cells.

27. A method for determining a memory cell storage state of a magnetoresistive memory cell, the method comprising:
determining a spin precession frequency provided by the magnetoresistive memory cell; and
determining the magnetoresistive memory cell storage state of the magnetoresistive memory cell based on the determined spin precession frequency.

28. The method of claim 27, further comprising:
providing a current to the magnetoresistive memory cell.

29. The method of claim 28,
wherein providing the current to the magnetoresistive memory cell comprises providing a DC current to the magnetoresistive memory cell.

30. The method of claim 27,
wherein the frequency is determined using a spectrum analyzer.

31. The method of claim 27,
wherein determining the memory cell storage state comprises determining the magnetoresistive memory cell storage state of the magnetoresistive memory cell based on a comparison of the determined spin precession frequency with at least one of a first predefined spin precession frequency associated with a first magnetoresistive memory cell storage state and a second predefined spin precession frequency associated with a second magnetoresistive memory cell storage state.

32. The method of claim 27,
wherein determining the memory cell storage state comprises determining the magnetoresistive memory cell storage state of the magnetoresistive memory cell based on a comparison of the determined spin precession frequency with a frequency threshold, which is arranged between a first predefined spin precession frequency associated with a first magnetoresistive memory cell storage state and a second predefined spin precession frequency associated with a second magnetoresistive memory cell storage state.

33. The method of claim 27, further comprising:
applying an external magnetic field to the magnetoresistive memory cell.

34. The method of claim 33,
wherein the applying an external magnetic field to the magnetoresistive memory cell comprises applying a fixed external magnetic field to the magnetoresistive memory cell.
